(19) United States
(12) Patent Application Publication
(10) Pub. No.: US 2025/0087427 A1
(43) Pub. Date: Mar. 13, 2025

(54) CAPACITOR ARRAY

(71) Applicant: Murata Manufacturing Co., Ltd., Nagaokakyo-shi (JP)

(72) Inventors: Takuya AMAMOTO, Nagaokakyo-shi (JP); Masanori YOSHIKAWA, Nagaokakyo-shi (JP)

(21) Appl. No.: 18/957,064

(22) Filed: Nov. 22, 2024

Related U.S. Application Data
(63) Continuation of application No. PCT/JP2023/019506, filed on May 25, 2023.

(30) Foreign Application Priority Data
Jun. 6, 2022 (JP) 2022-091679

(51) Int. Cl. H01G 9/10; H01G 4/38; H01G 9/045; H01G 9/055; H01G 9/15

(52) U.S. Cl. CPC H01G 9/10; H01G 4/38; H01G 9/045; H01G 9/055; H01G 9/15

(57) ABSTRACT

A capacitor array that includes: a capacitor part including a plurality of capacitor elements disposed in a planar arrangement in an in-plane direction orthogonal to a thickness direction, the plurality of capacitor elements including mutually adjacent capacitor elements that are separated from each other, wherein the plurality of capacitor elements each include a first electrode layer and a second electrode layer that face each other in the thickness direction with a dielectric layer interposed between the first electrode layer and the second electrode layer; a built-in member disposed at an outer periphery of the capacitor part in the in-plane direction; and a sealing layer that seals the capacitor part and the built-in member, wherein the built-in member has a higher melting temperature than the sealing layer.

### Cross Reference to Related Applications

The present application is a continuation of International application No. PCT/JP2023/019506, filed May 25, 2023, which claims priority to Japanese Patent Application No. 2022-091679, filed Jun. 6, 2022, the entire contents of each of which are incorporated herein by reference.

### TECHNICAL FIELD

The present disclosure relates to a capacitor array.

### BACKGROUND ART

An electrolytic capacitor is a type of capacitor. An electrolytic capacitor is fabricated by, for example, sealing a capacitor element with resin. The capacitor element includes an anode body, a dielectric layer disposed on a surface of the anode body, and a cathode part disposed on a surface of the dielectric layer.

Patent Document 1 discloses an electrolytic capacitor including a capacitor element, an anode terminal, a cathode terminal, and a resin sealing material. The capacitor element includes an anode body, a dielectric layer provided on the anode body, and a cathode part provided on the dielectric layer. The anode terminal is electrically connected to the anode body. The cathode terminal is electrically connected to the cathode part. The resin sealing material covers the capacitor element. The anode terminal and the cathode terminal are at least partially exposed from the resin sealing material. The anode body includes a foil including a valve metal. The electrolytic capacitor includes an insulating spacer on a surface of the cathode part.

Patent Document 2 discloses a wiring board with a built-in electronic component. At least two solid catalytic capacitors are built in the wiring board, and a connection terminal part and an inductor are provided on a surface of the wiring board. Each of the solid electrolytic capacitors includes a current collector layer disposed at least on one face of a valve metal sheet body (anode part). The connection terminal part includes an anode connection terminal part, and a cathode terminal connection part. The anode connection terminal part is electrically connected at least at two locations to the valve metal sheet body of the solid-state electrolytic capacitor via the wiring pattern mentioned above and the inductor and/or a via-electrode and/or a through-electrode. The cathode connection terminal part is electrically connected to the current collector layer (cathode part) of the solid-state electrolytic capacitor via the wiring pattern and/or the inductor and/or the via-electrode and/or the through-electrode. The inductor is formed in the shape of a conductor pattern.

Patent Document 1: Japanese Unexamined Patent Application Publication No. 2017-17122

Patent Document 2: Japanese Unexamined Patent Application Publication No. 2009-252764

### SUMMARY OF THE DISCLOSURE

To fabricate a capacitor array, a capacitor part with a plurality of capacitor elements disposed in a planar arrangement is sealed with resin. In this case, no capacitor element exists at the outer periphery of the capacitor part. Consequently, if the resin flows to the outer periphery of the capacitor part, the resulting capacitor array has a thickness that decreases toward the outer periphery.

In performing an embedding process using a resin layer as a post-processing step on such a capacitor array with non-uniform thickness, in order to maintain a uniform thickness in the final product obtained after the embedding process, the embedded resin layer covering the outer periphery of the capacitor array becomes thicker, whereas the embedded resin layer covering the central portion of the capacitor array becomes thinner. As a result, in creating a hole in the embedded resin layer to form a via-conductor for connection to the electrode part of the capacitor element, a machining defect may occur such that, for example, in the thicker portion of the embedded resin layer, it is not impossible to form the hole so as to extend to the electrode part of the capacitor element, or in the thinner portion of the embedded resin layer, the hole is formed so as to extend all the way into the electrode part of the capacitor element. It is thus desired to make the overall thickness of the capacitor array uniform.

The present disclosure makes it possible to provide a capacitor array with improved uniformity in overall thickness.

A capacitor array according to the present disclosure includes: a capacitor part including a plurality of capacitor elements disposed in a planar arrangement in an in-plane direction orthogonal to a thickness direction, the plurality of capacitor elements including mutually adjacent capacitor elements that are separated from each other, wherein the plurality of capacitor elements each include a first electrode layer and a second electrode layer that face each other in the thickness direction with a dielectric layer interposed between the first electrode layer and the second electrode layer; a built-in member disposed at an outer periphery of the capacitor part in the in-plane direction; and a sealing layer that seals the capacitor part and the built-in member, wherein the built-in member has a higher melting temperature than the sealing layer.

The present disclosure makes it possible to provide a capacitor array with improved uniformity in overall thickness.

### BRIEF DESCRIPTION OF THE DRAWINGS

FIG. 1 is a schematic cross-sectional view of an example of a capacitor array according to a first embodiment of the present disclosure.

FIG. 2 is a plan view, taken along a plane P1, of the capacitor array illustrated in FIG. 1.

FIG. 3 is a schematic cross-sectional view of a capacitor array according to an embodiment that includes a built-in member, illustrating the capacitor array after undergoing an embedding process.

FIG. 4 is a schematic cross-sectional view of a capacitor array according to a comparative example that includes no built-in member, illustrating the capacitor array after undergoing an embedding process.

FIG. 5 schematically illustrates, in plan view, an example of the step of providing a capacitor array sheet.

FIG. 6 schematically illustrates, in cross-sectional view, an example of the step of providing a capacitor array sheet.

FIG. 7 schematically illustrates, in plan view, an example of the step of cutting a capacitor array sheet.

FIG. 8 schematically illustrates, in cross-sectional view, an example of the step of cutting a capacitor array sheet.

FIG. 9 schematically illustrates, in plan view, an example of the step of placing a built-in member.

FIG. 10 schematically illustrates, in cross-sectional view, an example of the step of placing a built-in member.

FIG. 11 schematically illustrates, in plan view, an example of the step of thermocompression-bonding an insulating resin sheet.

FIG. 12 schematically illustrates, in cross-sectional view, an example of the step of thermocompression-bonding an insulating resin sheet.

FIG. 13 schematically illustrates, in plan view, an example of the step of obtaining a discrete capacitor array.

FIG. 14 schematically illustrates, in cross-sectional view, an example of the step of obtaining a discrete capacitor array.

FIG. 15 schematically illustrates, in cross-sectional view, a modification of the positioning of an outer electrode layer.

FIG. 16 schematically illustrates, in plan view, an example of the positioning of a built-in member.

FIG. 17 schematically illustrates, in plan view, a first modification of the positioning of a built-in member.

FIG. 18 schematically illustrates, in plan view, a second modification of the positioning of a built-in member.

FIG. 19 schematically illustrates, in plan view, a third modification of the positioning of a built-in member.

FIG. 20 schematically illustrates, in plan view, a fourth modification of the positioning of a built-in member.

FIG. 21 is a schematic cross-sectional view of an example of a capacitor array according to a second embodiment of the present disclosure.

FIG. 22 schematically illustrates, in plan view, an example of the step of providing a capacitor array sheet.

FIG. 23 schematically illustrates, in cross-sectional view, an example of the step of providing a capacitor array sheet.

FIG. 24 schematically illustrates, in plan view, an example of the step of cutting a capacitor array sheet.

FIG. 25 schematically illustrates, in cross-sectional view, an example of the step of cutting a capacitor array sheet.

FIG. 26 schematically illustrates, in plan view, an example of the step of thermocompression-bonding an insulating resin sheet.

FIG. 27 schematically illustrates, in cross-sectional view, an example of the step of thermocompression-bonding the insulating resin sheet.

FIG. 28 schematically illustrates, in plan view, an example of the step of obtaining a discrete capacitor array.

FIG. 29 schematically illustrates, in cross-sectional view, an example of the step of obtaining a discrete capacitor array.

FIG. 30 schematically illustrates, in plan view, another example of the step of obtaining discrete capacitor arrays.

FIG. 31 is a schematic cross-sectional view of another example of the capacitor array according to the second embodiment of the present disclosure.

### DESCRIPTION OF THE PREFERRED EMBODIMENTS

A capacitor array according to the present disclosure is described below. The present disclosure is not limited to the features described below but may be modified as appropriate without departing from the scope of the present disclosure. The present disclosure also encompasses combinations of individual preferred features described hereinbelow.

As used herein, terms indicative of the relationship between elements (e.g., “perpendicular”, “parallel”, and “orthogonal”), and terms indicative of a shape of an element are not intended to represent only their strict meanings but are meant to also include their substantial equivalents, for example, equivalents with deviations or differences of about a few percent.

It is needless to mention that embodiments described below are for illustrative purposes only, and features described in different embodiments may be substituted for or combined with each another. In the second and subsequent embodiments, matters or features identical to those according to the first embodiment are not described in further detail, and only differences from the first embodiment are described. In particular, the same or similar operational effects provided by the same or similar features are not mentioned for each individual embodiment.

In the following description, the expression “capacitor array according to the present disclosure” is used when no particular distinction is to be made between individual embodiments.

The drawings below are schematic in nature, and dimensions, scales such as the horizontal-to-vertical ratio, or other details in the drawings may differ from those of the actual product.

### First Embodiment

In a capacitor array according to a first embodiment of the present disclosure, a built-in member includes a configuration different from a configuration of a capacitor element.

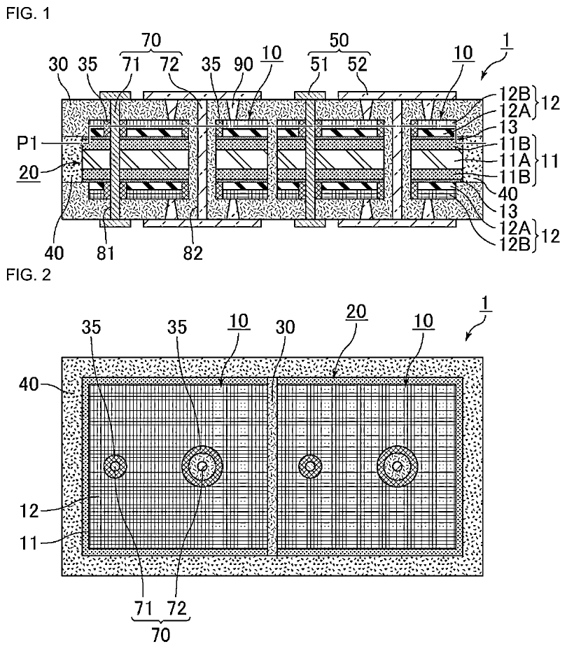

FIG. 1 is a schematic cross-sectional view of an example of the capacitor array according to the first embodiment of the present disclosure. FIG. 2 is a plan view, taken along a plane P1, of the capacitor array illustrated in FIG. 1.

A capacitor array 1 illustrated in FIGS. 1 and 2 includes a capacitor part 20, a sealing layer 30, and a built-in member 40. The capacitor part 20 includes a plurality of capacitor elements 10. The sealing layer 30 seals the capacitor part 20. The built-in member 40 is disposed inside the sealing layer 30 together with the capacitor part 20.

The capacitor array 1 may further include an outer electrode layer 50 disposed on a surface of the sealing layer 30. In that case, the outer electrode layer 50 includes, for example, a first outer electrode layer 51, and a second outer electrode layer 52.

The capacitor part 20 may include, with no particular limitation, any number of capacitor elements 10 greater than or equal to two.

In the capacitor part 20, the capacitor elements 10 are disposed in a planar arrangement in an in-plane direction orthogonal to the thickness direction (the up-down direction in FIG. 1).

In the capacitor part 20, the capacitor elements 10 may be disposed in a linear fashion, that is, in a single direction (e.g., the left-right direction in FIG. 2), or may be disposed in a planar fashion, that is, in a plurality of directions (e.g., in the left-right direction and the up-down direction in FIG. 2). The capacitor elements 10 may be disposed in a regular fashion, or may be disposed in an irregular fashion.

In the capacitor part 20, mutually adjacent capacitor elements 10 are separated from each other. It may suffice that mutually adjacent capacitor elements 10 be physically separated from each other. Accordingly, mutually adjacent capacitor elements 10 may be electrically separated from each other, or may be electrically connected to each other. If the capacitor part 20 includes three or more capacitor elements 10, a set of electrically separated capacitor elements 10, and a set of electrically connected capacitor elements 10 may coexist.

The area between mutually adjacent capacitor elements 10 that are separated from each other is preferably filled with an insulating material, such as the insulating material of the sealing layer 30.

Although not particularly limited, the spacing between mutually adjacent capacitor elements 10 is preferably greater than or equal to 15 μm, more preferably greater than or equal to 30 μm, or still more preferably greater than or equal to 50 μm. The spacing between mutually adjacent capacitor elements 10 is preferably less than or equal to 500 μm, more preferably less than or equal to 200 μm, or still more preferably less than or equal to 150 μm.

The spacing between mutually adjacent capacitor elements 10 may be constant in the thickness direction, or may decrease in the thickness direction. If, for example, the area between mutually adjacent capacitor elements 10 that are separated from each other is tapered as the spacing between the mutually adjacent capacitor elements 10 decreases in the thickness direction, this makes it easier to fill the area with an insulating material, such as the insulating material of the sealing layer 30.

The capacitor elements 10 each include a first electrode layer, a second electrode layer, and a dielectric layer. The first electrode layer and the second electrode layer face each other with in the thickness direction the dielectric layer interposed therebetween.

In the example illustrated in FIG. 1, the first electrode layer is an anode plate 11, and the second electrode layer is a cathode layer 12. The capacitor element 10 thus constitutes an electrolytic capacitor.

The anode plate 11 has, for example, a core 11A made of metal, and a porous part 11B disposed on at least one major face of the core 11A. A dielectric layer 13 is disposed on a surface of the porous part 11B, and the cathode layer 12 is disposed on a surface of the dielectric layer 13.

The cathode layer 12 includes, for example, a solid electrolyte layer 12A disposed on the surface of the dielectric layer 13. Preferably, the cathode layer 12 further includes a conductor layer 12B disposed on a surface of the solid electrolyte layer 12A. If the cathode layer 12 includes the solid electrolyte layer 12A, the capacitor element 10 constitutes a solid electrolytic capacitor.

The sealing layer 30 is preferably disposed on both major faces of the capacitor part 20 that are opposite from each other in the thickness direction of the capacitor part 20. The sealing layer 30 protects the capacitor elements 10.

The sealing layer 30 may be made up of only one layer, or may be made up of two or more layers. If the sealing layer 30 is made up of two or more layers, each layer may be made of the same material, or may be made of a different material.

The sealing layer 30 is formed through, for example, a method such as thermocompression-bonding an insulating resin sheet, or applying and subsequently heat-curing an insulating resin paste, in such a way that the sealing layer 30 seals the capacitor part 20.

As illustrated in FIGS. 1 and 2, the built-in member 40 is disposed at the outer periphery in the in-plane direction of the capacitor part 20. As illustrated in FIG. 1, the built-in member 40 is preferably sealed, together with the capacitor part 20, by the sealing layer 30 from opposite sides in the thickness direction.

In the example illustrated in FIGS. 1 and 2, the built-in member 40 includes a configuration different from a configuration of the capacitor element 10, and is electrically insulated from the capacitor part 20.

The built-in member 40 may be in contact with the capacitor part 20, or may be spaced apart from the capacitor part 20. If the built-in member 40 is spaced apart from the capacitor part 20, the area between the built-in member 40 and the capacitor part 20 is preferably filled with an insulating material, such as the insulating material of the sealing layer 30.

In the in-plane direction, the built-in member 40 may be exposed from the sealing layer 30, or may be unexposed from the sealing layer 30. In the thickness direction, the built-in member 40 is preferably unexposed from the sealing layer 30.

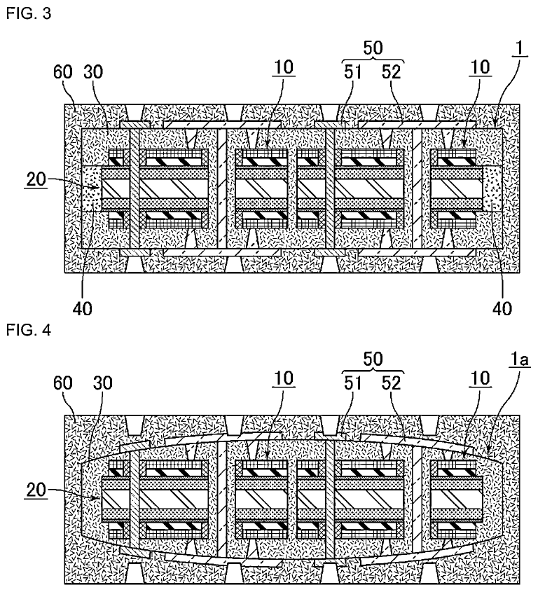

FIG. 3 is a schematic cross-sectional view of a capacitor array according to an embodiment that includes a built-in member, illustrating the capacitor array after undergoing an embedding process. FIG. 4 is a schematic cross-sectional view of a capacitor array according to a comparative example that includes no built-in member, illustrating the capacitor array after undergoing an embedding process.

In the capacitor array 1 according to the embodiment illustrated in FIG. 3, the built-in member 40 is disposed at the outer periphery in the in-plane direction of the capacitor part 20, and together with the capacitor part 20, the built-in member 40 is sealed with the sealing layer 30. This configuration helps to improve the uniformity of the overall thickness of the capacitor array 1.

In contrast, in a capacitor array la according to the comparative example illustrated in FIG. 4, the capacitor part 20 is simply sealed with the sealing layer 30. With this configuration alone, however, since no capacitor element 10 is present at the outer periphery of the capacitor part 20, the capacitor array 1a is likely to decrease in overall thickness toward the outer periphery.

This presents an issue with the capacitor array 1a illustrated in FIG. 4 when an embedded resin layer 60 is to be formed so as to cover the sealing layer 30 and the outer electrode layer 50. That is, in order to maintain a uniform thickness in the final product obtained after such an embedding process, the embedded resin layer 60 becomes thicker at the outer periphery and thinner in the central portion. As a result, in creating a hole in the embedded resin layer 60 to form a via-conductor for connection to the outer electrode layer 50, a machining defect may occur such that, for example, in the thicker portion of the embedded resin layer 60, it is not impossible to form the hole so as to extend to the outer electrode layer 50, or in the thinner portion of the embedded resin layer 60, the hole is formed so as to extend all the way into the outer electrode layer 50.

In contrast, the capacitor array 1 illustrated in FIG. 3 allows for improved thickness uniformity of the embedded resin layer 60 when the embedded resin layer 60 is to be formed so as to cover the sealing layer 30 and the outer electrode layer 50. This in turn facilitates machining when a via-conductor is to be formed in the embedded resin layer 60 to provide connection to the outer electrode layer 50. This also helps to reduce deformation at the outer periphery.

From the viewpoint of preventing thermally induced deformation, the built-in member 40 has a higher melting temperature than the sealing layer 30.

The melting temperature of each of the sealing layer 30 and the built-in member 40 can be determined by cutting out a portion of each of the sealing layer 30 and the built-in member 40 as a small test piece, raising the temperature of the small test piece, and measuring the temperature at which the small test piece melts. Alternatively, a melting point peak measured with a differential scanning calorimeter (DSC) may serve as such a melting temperature.

The built-in member 40 is made of, for example, an insulating material. In this case, the built-in member 40 is preferably made of insulating resin. Further, the built-in member 40 may contain a filler such as an inorganic filler.

Although the height (dimension in the thickness direction) of the built-in member 40 is not particularly limited, for a case where the capacitor array 1 is to be fabricated through a method described later, the height of the built-in member 40 is preferably equivalent to the thickness of the anode plate 11. The term “equivalent” as used in this case does not necessarily mean strictly equal, but may simply mean falling within a substantially equivalent range, for example, within a difference or deviation of about a few percent. The height of the built-in member 40 may differ from the thickness of the anode plate 11. Even if the built-in member 40 has a height less or greater than the thickness of the anode plate 11, the presence of the built-in member 40 makes it possible to provide a capacitor array with improved overall thickness uniformity as compared with a case where no built-in member 40 is present.

The width (dimension in the in-plane direction) of the built-in member 40 is not particularly limited, but is preferably greater than or equal to 15 μm, more preferably greater than or equal to 30 μm, or still more preferably greater than or equal to 50 μm. The width of the built-in member 40 is preferably less than or equal to 500 μm, more preferably less than or equal to 200 μm, or still more preferably less than or equal to 150 μm. The width of the built-in member 40 may be equal to the spacing between mutually adjacent capacitor elements 10, may be less than the spacing between mutually adjacent capacitor elements 10, or may be greater than the spacing between mutually adjacent capacitor elements 10.

The width of the built-in member 40 may be constant in the thickness direction, or may decrease in the thickness direction.

From the viewpoint of improving the overall thickness uniformity of the capacitor array 1, the built-in member 40 preferably occupies a large proportion of the entire capacitor array 1. An excessively large proportion occupied by the built-in member 40, however, results in a corresponding decrease in the proportion occupied by the capacitor elements 10. For this reason, in plan view seen in the thickness direction, the proportion of the area of the built-in member 40 relative to the area of the entire capacitor array 1 is preferably greater than or equal to 0.1% and less than or equal to 10%.

Reference is now made to a detailed configuration of the capacitor array 1.

Non-limiting examples of the shape of the capacitor element 10 in plan view seen in the thickness direction include: a polygon such as a rectangle (a square or an oblong), a non-rectangular quadrilateral, a triangle, a pentagon, or a hexagon; a circle; an ellipse; and a combination of these shapes. Alternatively, the shape of the capacitor element 10 in plan view may be, for example, an L-shape, a C-shape (U-shape), or a stepped shape.

The respective shapes of the capacitor elements 10 in plan view seen in the thickness direction may be identical to each other, may be different from each other, or may be different in part.

The respective areas of the capacitor elements 10 as seen in the thickness direction may be equal to each other, may be different from each other, or may be different in part.

If the capacitor element 10 includes the anode plate 11 and the cathode layer 12, the anode plate 11 is preferably made of a so-called valve metal that exhibits valve action. Non-limiting examples of the valve metal include: single metals such as aluminum, tantalum, niobium, titanium, and zirconium; and an alloy containing at least one of such single metals. Among these, aluminum or an aluminum alloy is preferred.

The anode plate 11 is preferably flat plate-shaped, or more preferably foil-shaped. Thus, as used herein, the term “plate-shaped” is meant to include “foil-shaped.”

It may suffice for the anode plate 11 to have the porous part 11B on at least one major face of the core 11A. That is, the anode plate 11 may have the porous part 11B only on one major face of the core 11A, or may have the porous part 11B on both major faces of the core 11A. The porous part 11B is preferably a porous layer formed on the surface of the core 11A, or more preferably an etched layer.

Prior to etching, the anode plate 11 preferably has a thickness of greater than or equal to 60 μm and less than or equal to 200 μm. The thickness of the core 11A that remains unetched after the etching is preferably greater than or equal to 15 μm and less than or equal to 70 μm. The porous part 11B has a thickness designed in accordance with the required withstand voltage and the required electrostatic capacity. The combined thickness of the porous parts 11B on opposite sides of the core 11A is preferably greater than or equal to 10 μm and less than or equal to 180 μm.

The porous part 11B preferably has a pore size of greater than or equal to 10 nm and less than or equal to 600 nm. The pore size of the porous part 11B refers to the median diameter D50 as measured with a mercury porosimeter. The pore size of the porous part 11B can be controlled through, for example, adjustment of various conditions used for etching.

The dielectric layer 13 disposed on the surface of the porous part 11B is porous, which reflects the surface condition of the porous part 11B. The dielectric layer 13 thus has a surface with minute irregularities. The dielectric layer 13 is preferably made of an oxide coating of the valve metal mentioned above. For example, if an aluminum foil is used as the anode plate 11, the dielectric layer 13 made of an oxide coating can be formed through application of anodization (also referred to as chemical conversion coating) to the surface of the aluminum foil in an aqueous solution containing, for example, ammonium adipate.

The thickness of the dielectric layer 13, which is designed in accordance with the required withstand voltage and the required electrostatic capacity, is preferably greater than or equal to 10 nm and less than or equal to 100 nm.

For a case where the cathode layer 12 includes the solid electrolyte layer 12A, non-limiting examples of the material constituting the solid electrolyte layer 12A include conductive polymers such as polypyrroles, polythiophenes, and polyanilines. Preferred among these are polythiophenes, particularly poly(3,4-ethylenedioxythiophene), which is called PEDOT. The conductive polymers mentioned above may contain a dopant such as polystyrene sulfonic acid (PSS). The solid electrolyte layer 12A preferably includes an inner layer that fills the pores (depressions) of the dielectric layer 13, and an outer layer that covers the dielectric layer 13.

The thickness of the solid electrolyte layer 12A from the surface of the porous part 11B is preferably greater than or equal to 2 μm and less than or equal to 20 μm.

Non-limiting examples of the method used to form the solid electrolyte layer 12A include: a method of forming a polymerized film of poly(3,4-ethylenedioxythiophene) on the surface of the dielectric layer 13 by use of a treatment solution containing monomers such as 3,4-ethylenedioxythiophene; and a method of applying a dispersion of polymers such as poly(3,4-ethylenedioxythiophene) onto the surface of the dielectric layer 13, and then drying the dispersion.

The solid electrolyte layer 12A can be formed in a predetermined region by coating of the surface of the dielectric layer 13 with the above-mentioned treatment solution or dispersion through a method such as sponge transfer, screen printing, application with a dispenser, or inkjet printing.

If the cathode layer 12 includes the conductor layer 12B, the conductor layer 12B includes at least one of a conductive resin layer or a metal layer. The conductor layer 12B may be made up of only a conductive resin layer or only a metal layer. The conductor layer 12B preferably covers the entire surface of the solid electrolyte layer 12A.

A non-limiting example of the conductive resin layer is a conductive adhesive layer containing at least one conductive filler selected from the group consisting of a silver filler, a copper filler, a nickel filler, and a carbon filler.

Non-limiting examples of the metal layer include a metal plating film, and a metal foil. The metal layer is preferably made of at least one metal selected from the group consisting of nickel, copper, silver, and an alloy containing such a metal as its major component. The term “major component” as used herein means an elemental component with the largest weight proportion.

The conductor layer 12B may include, for example, a carbon layer, and a copper layer. The carbon layer is disposed on a surface of the solid electrolyte layer 12A. The copper layer is disposed on a surface of the carbon layer.

The carbon layer is provided to electrically and mechanically connect the solid electrolyte layer 12A and the copper layer to each other. The carbon layer can be formed in a predetermined region by coating of the surface of the solid electrolyte layer 12A with a carbon paste through a method such as sponge transfer, screen printing, application with a dispenser, or inkjet printing. In this case, the stacking of the copper layer at the next step is preferably performed while the carbon layer is in its pre-dried, viscous state. The carbon layer preferably has a thickness of greater than or equal to 2 μm and less than or equal to 20 μm.

The copper layer can be formed in a predetermined region by coating of the surface of the carbon layer with a copper paste through a method such as sponge transfer, screen printing, application with a dispenser, or inkjet printing. The copper layer preferably has a thickness of greater than or equal to 2 μm and less than or equal to 20 μm.

The sealing layer 30 is made of an insulating material. In this case, the sealing layer 30 is preferably made of insulating resin.

Non-limiting examples of the insulating resin constituting the sealing layer 30 include epoxy resin and phenolic resin.

Preferably, the sealing layer 30 further includes a filler.

A non-limiting example of the filler included in the sealing layer 30 is an inorganic filler such as silica particles or alumina particles.

For example, a layer such as a stress relaxation layer or a moisture barrier may be disposed between the capacitor part 20 and the sealing layer 30.

As illustrated in FIG. 1, the capacitor array 1 preferably further includes a through-hole conductor 70.

The through-hole conductor 70 preferably includes at least one of a first through-hole conductor 71 or a second through-hole conductor 72. The first through-hole conductor 71 is electrically connected to the first electrode layer (e.g., the anode plate 11) of the capacitor element 10. The second through-hole conductor 72 is electrically connected to the second electrode layer (e.g., the cathode layer 12) of the capacitor element 10.

The first through-hole conductor 71 extends through the capacitor part 20 and the sealing layer 30 in the thickness direction.

It may suffice that the first through-hole conductor 71 be disposed on at least the inner wall surface of a first through-hole 81, which extends through the capacitor part 20 and the sealing layer 30 in the thickness direction. The first through-hole conductor 71 may be disposed only on the inner wall surface of the first through-hole 81, or may be disposed in the entire interior of the first through-hole 81.

The first through-hole conductor 71 is preferably electrically connected at the inner wall surface of the first through-hole 81 to the anode plate 11. More specifically, the first through-hole conductor 71 is preferably electrically connected to an end face of the anode plate 11 that faces the inner wall surface of the first through-hole 81 in the in-plane direction. The anode plate 11 is thus electrically led out externally via the first through-hole conductor 71.

The core 11A and the porous part 11B are preferably exposed at an end face of the anode plate 11 that is electrically connected to the first through-hole conductor 71. In this case, in addition to the core 11A, the porous part 11B is also electrically connected to the first through-hole conductor 71.

When viewed in the thickness direction, the first through-hole conductor 71 is preferably electrically connected to the anode plate 11 across the entire circumference of the first through-hole 81. This facilitates reduced connection resistance between the anode plate 11 and the first through-hole conductor 71, and consequently facilitates reduced equivalent series resistance (ESR) of the capacitor element 10.

The first through-hole conductor 71 is formed as follows, for example. First, the first through-hole 81, which extends through the capacitor part 20 and the sealing layer 30 in the thickness direction, is formed through machining such as drilling or laser machining. Then, the inner wall surface of the first through-hole 81 is metallized with a metallic material containing a low-resistance metal such as copper, gold, or silver to thereby form the first through-hole conductor 71. In forming the first through-hole conductor 71, the machining is facilitated by, for example, metallizing the inner wall surface of the first through-hole 81 through a process such as electroless copper plating or electrolytic copper plating. Other than the method of metallizing the inner wall surface of the first through-hole 81, another method that may be used to form the first through-hole conductor 71 is to fill the first through-hole 81 with a material such as a metallic material or a composite of a metal and resin.

An anode connection layer may be disposed between the anode plate 11 and the first through-hole conductor 71 in the in-plane direction. That is, the anode plate 11 and the first through-hole conductor 71 may be electrically connected to each other via the anode connection layer.

As described above, the anode connection layer is disposed between the anode plate 11 and the first through-hole conductor 71 in the in-plane direction. The anode connection layer thus serves as a barrier layer for the anode plate 11, more specifically, a barrier layer for the core 11A and for the porous part 11B. The presence of the anode connection layer serving as a barrier layer for the anode plate 11 reduces the risk of the anode plate 11 dissolving during treatment with a chemical solution that is performed to form the outer electrode layer 50 (e.g., the first outer electrode layer 51). This in turn reduces the risk of the chemical solution entering the capacitor part 20, and consequently facilitates improved reliability of the capacitor array 1.

The anode connection layer preferably includes a layer containing nickel as a major component. This allows for reduced damage to the metal (e.g., aluminum) constituting the anode plate 11, and consequently facilitates improved barrier properties of the anode connection layer with respect to the anode plate 11.

No anode connection layer may be disposed between the anode plate 11 and the first through-hole conductor 71 in the in-plane direction. In this case, the first through-hole conductor 71 may be directly connected to the end face of the anode plate 11.

If the first through-hole conductor 71 is disposed only on the inner wall surface of the first through-hole 81, the first through-hole 81 may be provided with a resin-filled part filled with a resin material. In that case, the resin-filled part is located in a space inside the first through-hole 81 that is surrounded by the first through-hole conductor 71. The presence of the resin-filled part results in elimination of space inside the first through-hole 81. This leads to reduced risk of delamination of the first through-hole conductor 71.

The first outer electrode layer 51 is electrically connected to the first electrode layer (e.g., the anode plate 11) of the capacitor element 10. In the example illustrated in FIG. 1, the first outer electrode layer 51 is disposed on the surface of the first through-hole conductor 71, and serves as a connection terminal for the capacitor array 1 (the capacitor element 10). In the example illustrated in FIG. 1, the first outer electrode layer 51 is electrically connected to the anode plate 11 via the first through-hole conductor 71, and serves as a connection terminal for the anode plate 11.

A non-limiting example of the material constituting the first outer electrode layer 51 is a metallic material containing a low-resistance metal such as copper, gold, or silver. In this case, the first outer electrode layer 51 is formed by, for example, plating applied on the surface of the first through-hole conductor 71.

From the viewpoint of improving the adhesion between the first outer electrode layer 51 and another member, which in this case is the adhesion between the first outer electrode layer 51 and the first through-hole conductor 71, the first outer electrode layer 51 may be made of a mixture of resin and at least one conductive filler selected from the group consisting of a silver filler, a copper filler, a nickel filler, and a carbon filler.

The second through-hole conductor 72 extends through the capacitor part 20 and the sealing layer 30 in the thickness direction.

It may suffice that the second through-hole conductor 72 be disposed on at least the inner wall surface of a second through-hole 82, which extends through the capacitor part 20 and the sealing layer 30 in the thickness direction. The second through-hole conductor 72 may be disposed only on the inner wall surface of the second through-hole 82, or may be disposed in the entire interior of the second through-hole 82.

The second through-hole conductor 72 is formed as follows, for example. First, a through-hole that extends through the capacitor part 20 in the thickness direction is formed through machining such as drilling or laser machining. Subsequently, the through-hole mentioned above is filled with an insulating material. The portion of the through-hole that is now filled with the insulating material is then subjected to machining such as drilling or laser machining to thereby form the second through-hole 82. At this time, the second through-hole 82 is formed with a diameter less than the diameter of the through-hole filled with the insulating material. This results in a state in which the insulating material exists between the previously formed through-hole and the second through-hole 82 in the in-plane direction. Subsequently, the inner wall surface of the second through-hole 82 is metallized with a metallic material containing a low-resistance metal such as copper, gold, or silver to thereby form the second through-hole conductor 72. In forming the second through-hole conductor 72, the machining is facilitated by, for example, metallizing the inner wall surface of the second through-hole 82 through a process such as electroless copper plating or electrolytic copper plating. Other than the method of metallizing the inner wall surface of the second through-hole 82, another method that may be used to form the second through-hole conductor 72 is to fill the second through-hole 82 with a material such as a metallic material or a composite of a metal and resin.

If the second through-hole conductor 72 is disposed only on the inner wall surface of the second through-hole 82, the second through-hole 82 may be provided with a resin-filled part filled with a resin material. In that case, the resin-filled part is located in a space inside the second through-hole 82 that is surrounded by the second through-hole conductor 72. The presence of the resin-filled part results in elimination of space inside the second through-hole 82. This leads to reduced risk of delamination of the second through-hole conductor 72.

The second outer electrode layer 52 is electrically connected to the second electrode layer (e.g., the cathode layer 12) of the capacitor element 10. In the example illustrated in FIG. 1, the second outer electrode layer 52 is disposed on the surface of the second through-hole conductor 72, and serves as a connection terminal for the capacitor array 1 (the capacitor element 10).

A non-limiting example of the material constituting the second outer electrode layer 52 is a metallic material containing a low-resistance metal such as copper, gold, or silver. In this case, the second outer electrode layer 52 is formed by, for example, plating applied on the surface of the second through-hole conductor 72.

From the viewpoint of improving the adhesion between the second outer electrode layer 52 and another member, which in this case is the adhesion between the second outer electrode layer 52 and the second through-hole conductor 72, the second outer electrode layer 52 may be made of a mixture of resin and at least one conductive filler selected from the group consisting of a silver filler, a copper filler, a nickel filler, and a carbon filler.

Although the material constituting the first outer electrode layer 51, and the material constituting the second outer electrode layer 52 are preferably identical to each other at least in kind, these materials may be different from each other.

In the example illustrated in FIG. 1, the capacitor elements 10 are each provided with the first outer electrode layer 51 electrically connected to the anode plate 11, and the second outer electrode layer 52 electrically connected to the cathode layer 12. Alternatively, however, at least one of the first outer electrode layer 51 or the second outer electrode layer 52 may be common to the capacitor elements 10.

In the example illustrated in FIG. 1, the first outer electrode layer 51 and the second outer electrode layer 52 are disposed on both major faces of the sealing layer 30. Alternatively, however, the first outer electrode layer 51 and the second outer electrode layer 52 may be disposed only on one major face of the sealing layer 30.

Although not illustrated in FIG. 1, the through-hole conductor 70 may include a third through-hole conductor, which is electrically connected to neither of the first electrode layer (e.g., the anode plate 11) and the second electrode layer (e.g., the cathode layer 12) of the capacitor element 10.

As illustrated in FIG. 1, the capacitor array 1 preferably further includes a via-conductor 90.

The via-conductor 90 extends through the sealing layer 30 in the thickness direction, and is connected to the cathode layer 12 and the second outer electrode layer 52.

A non-limiting example of the material constituting the via-conductor 90 is a metallic material containing a low-resistance metal such as copper, gold, or silver.

The via-conductor 90 is formed through, for example, application of a plating of the above-mentioned metallic material to the inner wall surface of a through-hole that extends through the sealing layer 30 in the thickness direction, or filling of the through-hole with a conductive paste and the subsequent application of heat treatment.

In the example illustrated in FIG. 1, the second through-hole conductor 72 is electrically connected to the cathode layer 12 via the second outer electrode layer 52 and the via-conductor 90.

In the example illustrated in FIG. 1, the second outer electrode layer 52 is electrically connected to the cathode layer 12 via the via-conductor 90, and serves as a connection terminal for the cathode layer 12.

If the capacitor array 1 includes the through-hole conductor 70, the capacitor element 10 preferably further includes an insulating layer 35 disposed at least at one major face of the anode plate 11 and around the through-hole conductor 70.

In the example illustrated in FIGS. 1 and 2, the insulating layer 35 is disposed between the first through-hole conductor 71 and the cathode layer 12. In the example illustrated in FIGS. 1 and 2, the space between the second through-hole conductor 72 and the capacitor element 10 is filled with an insulating material, such as the insulating material of the sealing layer 30, and the insulating layer 35 is disposed between the insulating material and the cathode layer 12.

Although not illustrated in FIGS. 1 and 2, the capacitor element 10 may further include an insulating layer disposed at least at one major face of the anode plate 11 and surrounding the periphery of the cathode layer 12. Surrounding the periphery of the cathode layer 12 with the insulating layer ensures insulation between the anode plate 11 and the cathode layer 12, and consequently prevents short-circuiting therebetween.

Although the insulating layer may surround part of the periphery of the cathode layer 12, the insulating layer preferably surrounds the entire periphery of the cathode layer 12.

The insulating layer such as the insulating layer 35 is made of an insulating material. In this case, the insulating layer is preferably made of insulating resin.

Non-limiting examples of the insulating resin constituting the insulating layer such as the insulating layer 35 include polyphenyl sulfone resin, polyether sulfone resin, cyanate ester resin, fluororesin (e.g., tetrafluoroethylene or tetrafluoroethylene-perfluoroalkyl vinyl ether copolymer), polyimide resin, polyamide-imide resin, epoxy resin, and derivatives or precursors of these resins.

The insulating layer such as the insulating layer 35 may be made of the same resin as the resin constituting the sealing layer 30. Unlike the sealing layer 30, if the insulating layer contains an inorganic filler, this can adversely affect the effective capacitance portion of the capacitor element 10. Therefore, the insulating layer is preferably made up of resin alone.

The insulating layer such as the insulating layer 35 can be formed in a predetermined region by, for example, coating of the surface of the porous part 11B with a mask material, such as a composition including insulating resin, through a method such as sponge transfer, screen printing, application with a dispenser, or inkjet printing.

The insulating layer such as the insulating layer 35 may be formed with respect to the porous part 11B before the dielectric layer 13 is formed, or may be formed with respect to the porous part 11B after the dielectric layer 13 is formed.

The capacitor array 1 illustrated in FIGS. 1 and 2 can be manufactured through, for example, a method described below.

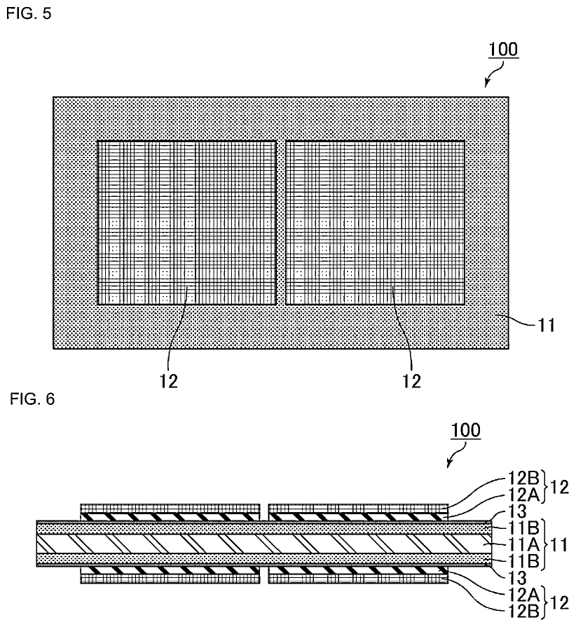

FIG. 5 schematically illustrates, in plan view, an example of the step of providing a capacitor array sheet. FIG. 6 schematically illustrates, in cross-sectional view, an example of the step of providing a capacitor array sheet.

At the step illustrated in FIGS. 5 and 6, a capacitor array sheet 100 with the cathode layer 12 disposed at a predetermined region of the anode plate 11 is provided.

First, the anode plate 11 made of a valve metal is prepared. As illustrated in FIG. 6, the dielectric layer 13 is disposed on at least one major face of the anode plate 11.

For example, the dielectric layer 13 is formed on the surface of the porous part 11B through application of anodization to the anode plate 11 having the porous part 11B disposed on at least one major face of the core 11A.

Alternatively, a chemically converted foil may be prepared as the anode plate 11 with the dielectric layer 13 disposed on the surface of the porous part 11B.

Although not illustrated in FIGS. 5 and 6, to divide individual capacitor elements 10 (see FIGS. 1 and 2) from each other, for example, an insulating layer may be formed in a predetermined region by coating the surface of the dielectric layer 13 with insulating resin through a method such as sponge transfer, screen printing, or application with a dispenser.

As required, the insulating layer 35 (see FIGS. 1 and 2) may be formed in a region where the through-hole conductor 70 (see FIGS. 1 and 2) is to be formed.

Subsequently, for example, the solid electrolyte layer 12A is formed on the surface of the dielectric layer 13, and then the conductor layer 12B is formed on the surface of the solid electrolyte layer 12A. The cathode layer 12 is thus formed.

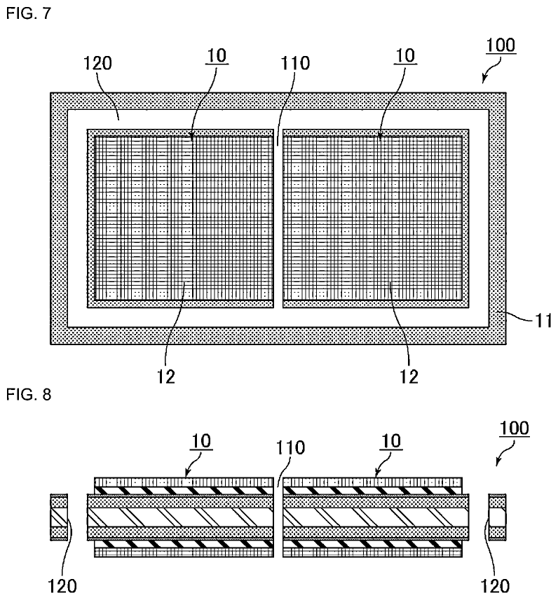

FIG. 7 schematically illustrates, in plan view, an example of the step of cutting a capacitor array sheet. FIG. 8 schematically illustrates, in cross-sectional view, an example of the step of cutting a capacitor array sheet.

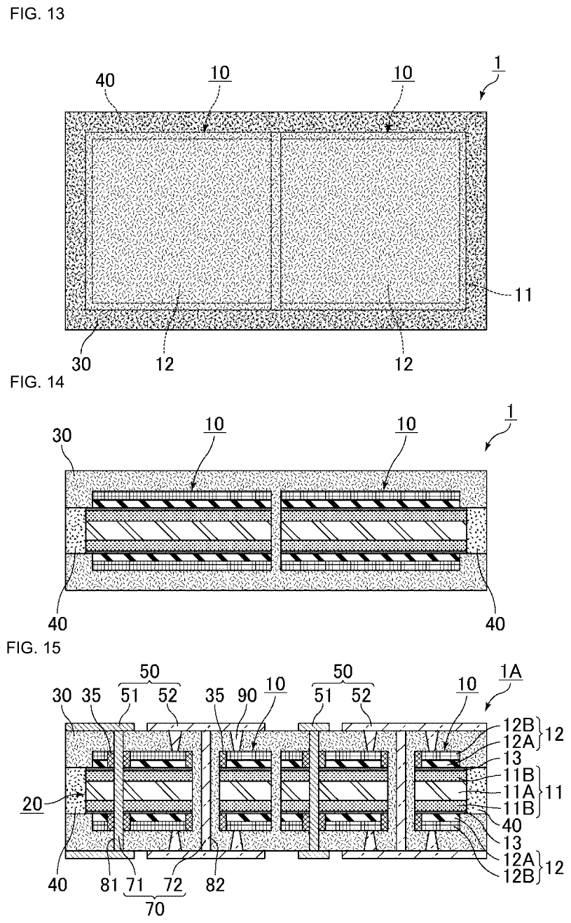

At the step illustrated in FIGS. 7 and 8, a through-groove 110 is formed by cutting the capacitor array sheet 100. The capacitor array sheet 100 is thus split into individual capacitor elements 10. Further, a slit 120 is formed by removing the area at the outer periphery of a portion of the capacitor array sheet 100 that will become the final product (see FIGS. 13 and 14).

Non-limiting examples of the method for forming the through-groove 110 and the slit 120 include laser machining, and cutting with a dicing machine. The method for forming the through-groove 110 may be the same as or different from the method for forming the slit 120. The order in which to form the through-groove 110 and the slit 120 is not particularly limited.

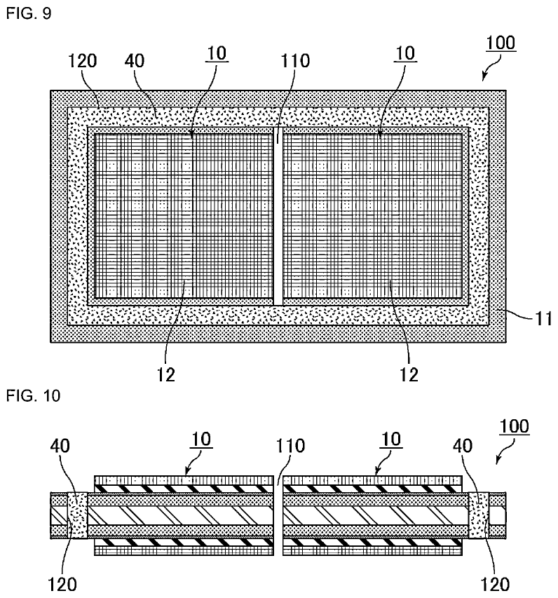

FIG. 9 schematically illustrates, in plan view, an example of the step of placing a built-in member. FIG. 10 schematically illustrates, in cross-sectional view, an example of the step of placing a built-in member.

At the step illustrated in FIGS. 9 and 10, the built-in member 40 is placed inside the slit 120. For example, an insulating material with a higher melting temperature than the insulating material of the sealing layer 30 is poured into the slit 120.

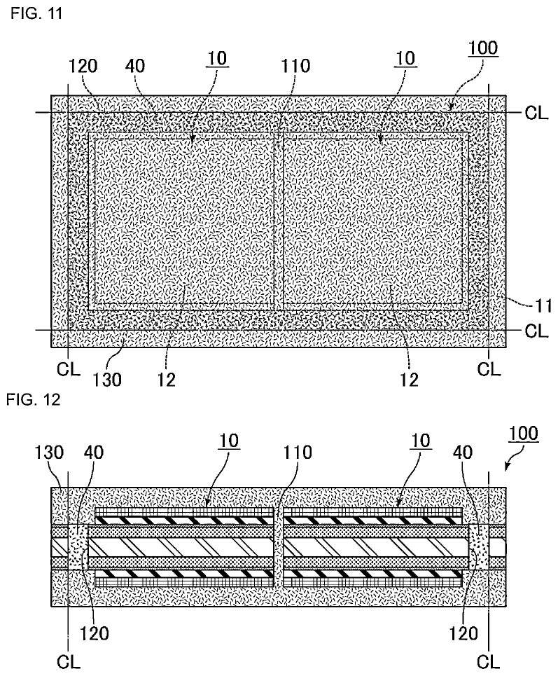

FIG. 11 schematically illustrates, in plan view, an example of the step of thermocompression-bonding an insulating resin sheet. FIG. 12 schematically illustrates, in cross-sectional view, an example of the step of thermocompression-bonding an insulating resin sheet.

At the step illustrated in FIGS. 11 and 12, for example, an insulating resin sheet 130 is thermocompression-bonded from both major sides of the capacitor array sheet 100. At this time, the interior of the through-groove 110 becomes filled with insulating resin.

FIG. 13 schematically illustrates, in plan view, an example of the step of obtaining a discrete capacitor array. FIG. 14 schematically illustrates, in cross-sectional view, an example of the step of obtaining a discrete capacitor array.

At the step illustrated in FIGS. 13 and 14, the capacitor array sheet 100 and the insulating resin sheet 130 are cut along a cutting line CL illustrated in FIGS. 11 and 12 to obtain a discrete capacitor array 1. At this time, cutting may be performed in such a way that the built-in member 40 is exposed from the sealing layer 30 in the in-plane direction, or in such a way that the built-in member 40 is not exposed from the sealing layer 30 in the in-plane direction. If the built-in member 40 is exposed from the sealing layer 30, cutting may be performed over the built-in member 40.

Then, as required, the outer electrode layer 50, the through-hole conductor 70, and the via-conductor 90 are formed. The capacitor array 1 illustrated in FIGS. 1 and 2 can be thus manufactured.

FIG. 15 schematically illustrates, in cross-sectional view, a modification of the positioning of the outer electrode layer.

As with a capacitor array 1A illustrated in the FIG. 15, the outer electrode layer 50 may be disposed directly above the built-in member 40 in the thickness direction.

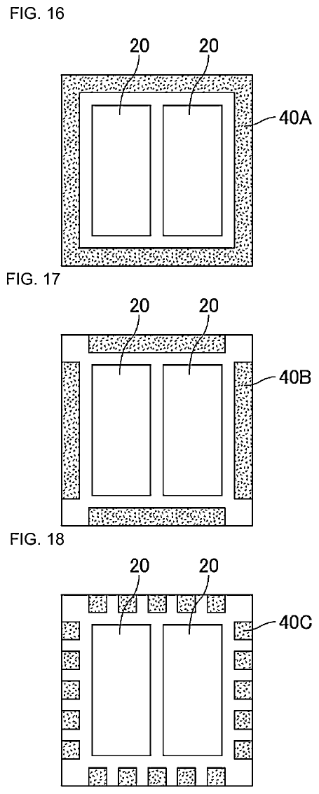

FIG. 16 schematically illustrates, in plan view, an example of the positioning of a built-in member.

In the example illustrated in FIG. 16, a built-in member 40A is disposed continuously along the entire outermost periphery of the final product portion.

FIG. 17 schematically illustrates, in plan view, a first modification of the positioning of a built-in member.

In the example illustrated in FIG. 17, a built-in member 40B is not disposed at part of the outermost periphery of the final product portion. In FIG. 17, no built-in member 40B is disposed at four corner areas. Alternatively, however, no built-in member 40B may be disposed at least at one corner area.

FIG. 18 schematically illustrates, in plan view, a second modification of the positioning of a built-in member.

In the example illustrated in FIG. 18, a built-in member 40C is disposed at spaced locations at the outermost periphery of the final product portion. The spacings between adjacent portions of the built-in member 40C may be the same, may be different, or may be different in part. In FIG. 18, no built-in member 40C is disposed at four corner areas. Alternatively, however, no built-in member 40C may be disposed at least at one corner area.

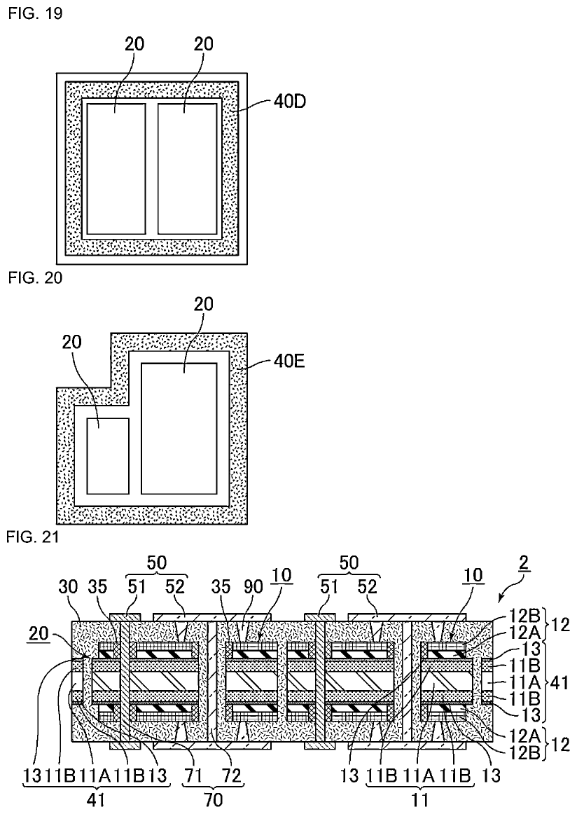

FIG. 19 schematically illustrates, in plan view, a third modification of the positioning of a built-in member.

In the example illustrated in FIG. 19, a built-in member 40D is disposed along and inside the outermost periphery of the final product portion. In this case, the built-in member 40D may be disposed continuously, may be absent in part, or may be disposed at spaced locations.

FIG. 20 schematically illustrates, in plan view, a fourth modification of the positioning of a built-in member.

In the example illustrated in FIG. 20, a built-in member 40E is disposed along the contour of the final product portion. In this case, the built-in member 40E may be disposed continuously, may be absent in part, or may be disposed at spaced locations. The built-in member 40E may be disposed along the contour of the final product portion and inside the outermost periphery of the final product portion.

### Second Embodiment

In a capacitor array according to a second embodiment of the present disclosure, a built-in member includes a configuration identical to a configuration of the capacitor element.

FIG. 21 is a schematic cross-sectional view of an example of the capacitor array according to the second embodiment of the present disclosure.

In a capacitor array 2 illustrated in FIG. 21, a built-in member 41 includes a configuration identical to a configuration of the capacitor element 10, and spaced apart and electrically insulated from the capacitor part 20. The capacitor array 2 illustrated in FIG. 21 is identical in configuration to the capacitor array 1 illustrated in FIG. 1, except that the capacitor array 2 includes the built-in member 41 instead of the built-in member 40.

In the capacitor array 2, the built-in member 41 includes a configuration identical to the configuration of the capacitor element 10. This obviates the need to provide another material, unlike with the built-in member 40 that includes a configuration different from a configuration of the capacitor element 10. This in turn can facilitate manufacture of the capacitor array 2.

In the example illustrated in FIG. 21, the built-in member 41 includes a configuration identical to a configuration of the anode plate 11, and spaced apart and electrically insulated from the capacitor part 20. The built-in member 41 thus has a higher melting temperature than the sealing layer 30.

Like the anode plate 11, the built-in member 41 preferably has the core 11A made of metal, and the porous part 11B disposed on at least one major face of the core 11A. The dielectric layer 13 may be disposed on the surface of the porous part 11B.

As illustrated in FIG. 21, the built-in member 41 is disposed at the outer periphery in the in-plane direction of the capacitor part 20. As illustrated in FIG. 21, the built-in member 41 is preferably sealed, together with the capacitor part 20, by the sealing layer 30 from opposite sides in the thickness direction.

The built-in member 41 is spaced apart from the capacitor part 20. The space between the built-in member 41 and the capacitor part 20 is preferably filled with an insulating material, such as the insulating material of the sealing layer 30.

Although not particularly limited, the width between the built-in member 41 and the capacitor part 20 is preferably greater than or equal to 15 μm, more preferably greater than or equal to 30 μm, or still more preferably greater than or equal to 50 μm. The width between the built-in member 41 and the capacitor part 20 is preferably less than or equal to 500 μm, more preferably less than or equal to 200 μm, or still more preferably less than or equal to 150 μm. The width between the built-in member 41 and the capacitor part 20 may be equal to the spacing between mutually adjacent capacitor elements 10, may be less than the spacing between mutually adjacent capacitor elements 10, or may be greater than the spacing between mutually adjacent capacitor elements 10.

In the in-plane direction, the built-in member 41 may be exposed from the sealing layer 30, or may be unexposed from the sealing layer 30. In the thickness direction, the built-in member 41 is preferably unexposed from the sealing layer 30.

Although the height (dimension in the thickness direction) of the built-in member 41 is not particularly limited, for a case where the anode plate 11 and the built-in member 41 are to be fabricated from the capacitor array sheet 100 by a method described later, the height of the built-in member 41 is preferably equivalent to the thickness of the anode plate 11. The term “equivalent” as used in this case does not necessarily mean strictly equal, but may simply mean falling within a substantially equivalent range, for example, within a difference or deviation of about a few percent.

The width (dimension in the in-plane direction) of the built-in member 41 is not particularly limited, but is preferably greater than or equal to 15 μm, more preferably greater than or equal to 30 μm, or still more preferably greater than or equal to 50 μm. The width of the built-in member 41 is preferably less than or equal to 500 μm, more preferably less than or equal to 200 μm, or still more preferably less than or equal to 150 μm. The width of the built-in member 41 may be equal to the spacing between mutually adjacent capacitor elements 10, may be less than the spacing between mutually adjacent capacitor elements 10, or may be greater than the spacing between mutually adjacent capacitor elements 10. The width of the built-in member 41 may be equal to the spacing between the built-in member 41 and the capacitor part 20, may be less than the spacing between the built-in member 41 and the capacitor part 20, or may be greater than the spacing between the built-in member 41 and the capacitor part 20.

From the viewpoint of improving the overall thickness uniformity of the capacitor array 2, the built-in member 41 preferably occupies a large proportion of the entire capacitor array 2. An excessively large proportion occupied by the built-in member 41, however, results in a corresponding decrease in the proportion occupied by the capacitor elements 10. For this reason, in plan view seen in the thickness direction, the proportion of the area of the built-in member 41 relative to the area of the entire capacitor array 2 is preferably greater than or equal to 0.1% and less than or equal to 10%.

The capacitor array 2 illustrated in FIG. 21 can be manufactured through, for example, a method described below.

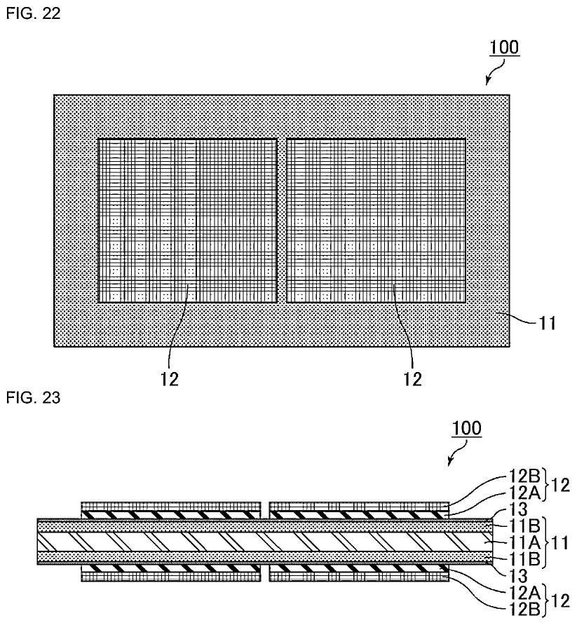

FIG. 22 schematically illustrates, in plan view, an example of the step of providing a capacitor array sheet. FIG. 23 schematically illustrates, in plan view, an example of the step of providing a capacitor array sheet.

At the step illustrated in FIGS. 22 and 23, as with the step illustrated in FIGS. 5 and 6, the capacitor array sheet 100 with the cathode layer 12 disposed at a predetermined region of the anode plate 11 is provided.

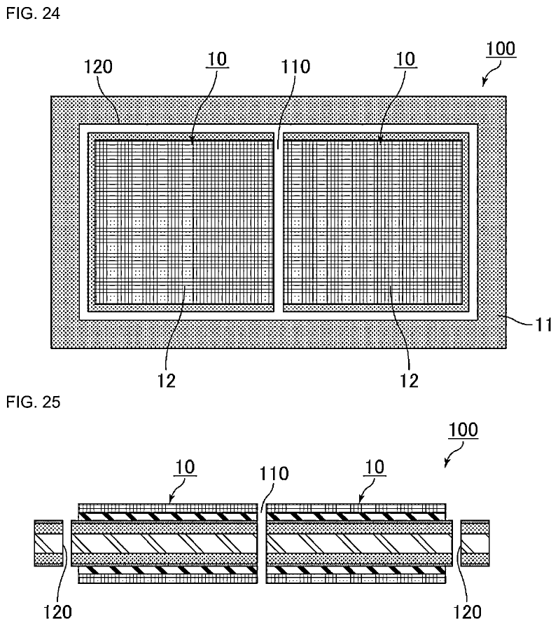

FIG. 24 schematically illustrates, in plan view, an example of the step of cutting a capacitor array sheet. FIG. 25 schematically illustrates, in cross-sectional view, an example of the step of cutting a capacitor array sheet.

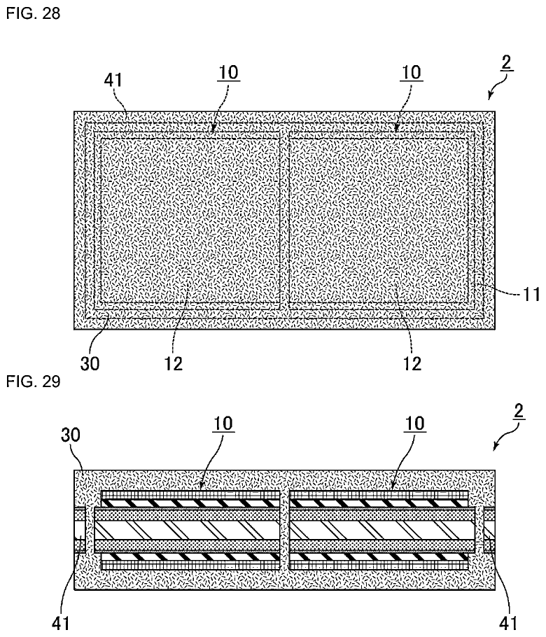

At the step illustrated in FIGS. 24 and 25, the through-groove 110 is formed by cutting the capacitor array sheet 100. The capacitor array sheet 100 is thus split into individual capacitor elements 10. Further, the slit 120 is formed by removing the area inside the outer periphery of the final product portion (see FIGS. 28 and 29).

Non-limiting examples of the method for forming the through-groove 110 and the slit 120 include laser machining, and cutting with a dicing machine. The method for forming the through-groove 110 may be the same as or different from the method for forming the slit 120. The order in which to form the through-groove 110 and the slit 120 is not particularly limited.

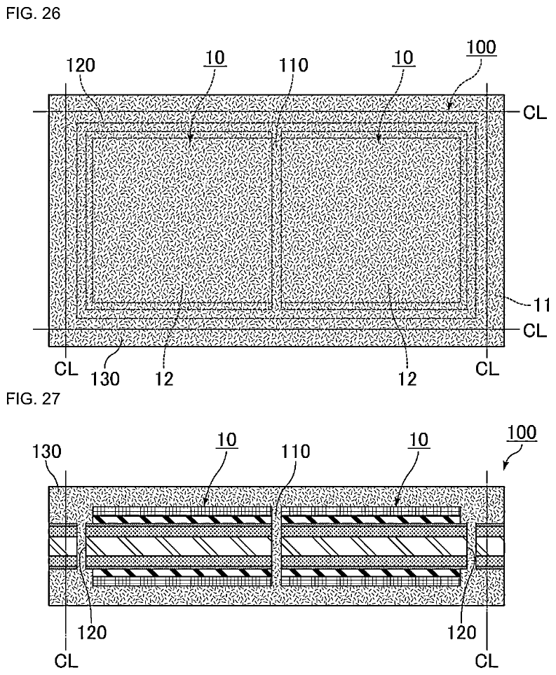

FIG. 26 schematically illustrates, in plan view, an example of the step of thermocompression-bonding an insulating resin sheet. FIG. 27 schematically illustrates, in cross-sectional view, an example of the step of thermocompression-bonding an insulating resin sheet.

At the step illustrated in FIGS. 26 and 27, for example, the insulating resin sheet 130 is thermocompression-bonded from both major sides of the capacitor array sheet 100. At this time, the interior of each of the through-groove 110 and the slit 120 becomes filled with insulating resin.

FIG. 28 schematically illustrates, in plan view, an example of the step of obtaining a discrete capacitor array. FIG. 29 schematically illustrates, in cross-sectional view, an example of the step of obtaining a discrete capacitor array.

At the step illustrated in FIGS. 28 and 29, the capacitor array sheet 100 and the insulating resin sheet 130 are cut along the cutting line CL illustrated in FIGS. 26 and 27 into each discrete capacitor array 2. As a result, at the outer periphery of the final product portion, a portion of the anode plate 11 remains as the built-in member 41. The built-in member 41 is preferably exposed from the sealing layer 30 in the in-plane direction.

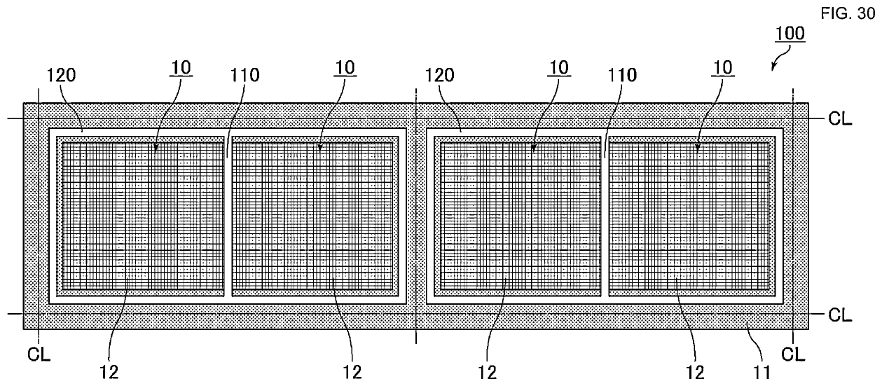

FIG. 30 schematically illustrates, in plan view, an example of the step of obtaining discrete capacitor arrays.

After the insulating resin sheet 130 (not illustrated) is thermocompression-bonded from both major sides of the capacitor array sheet 100 that is in the state illustrated in FIG. 30, the capacitor array sheet 100 and the insulating resin sheet 130 may be cut along the cutting line CL illustrated in FIG. 30. In this case, the built-in member 41 (see FIG. 28) is shared between mutually adjacent capacitor arrays 2. This allows a plurality of capacitor arrays 2 to be manufactured by performing cutting once.

Then, as required, the outer electrode layer 50, the through-hole conductor 70, and the via-conductor 90 are formed. The capacitor array 2 illustrated in FIG. 21 can be thus manufactured.

In an alternative configuration of the capacitor array 2 illustrated in FIG. 21, as in the capacitor array 1A illustrated in the FIG. 15, the outer electrode layer 50 may be disposed directly above the built-in member 41 in the thickness direction.

In the example illustrated in FIG. 21, the capacitor elements 10 are each provided with the first outer electrode layer 51 electrically connected to the anode plate 11, and the second outer electrode layer 52 electrically connected to the cathode layer 12. Alternatively, however, at least one of the first outer electrode layer 51 or the second outer electrode layer 52 may be common to the capacitor elements 10.

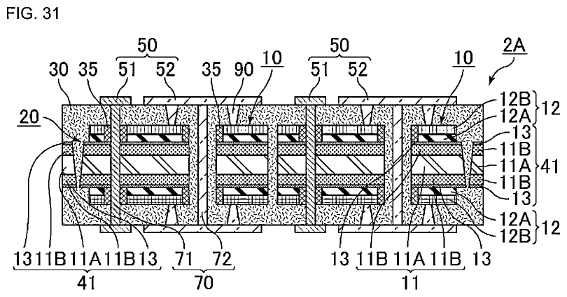

FIG. 31 is a schematic cross-sectional view of another example of a capacitor array according to the second embodiment of the present disclosure.

In a capacitor array 2A illustrated in FIG. 31, the width between the built-in member 41 and the capacitor part 20 decreases in the thickness direction. The capacitor array 2A is otherwise identical in configuration to the capacitor array 2 illustrated in FIG. 21.

The width between the built-in member 41 and the capacitor part 20 may be constant in the thickness direction as illustrated in FIG. 21, or may decrease in the thickness direction as illustrated in FIG. 31. If, as illustrated in FIG. 31, the area between the built-in member 41 and the capacitor part 20 is tapered as the area decreases in width in the thickness direction, this makes it easier to fill the area with an insulating material, such as the insulating material of the sealing layer 30.

### Other Embodiments

The capacitor array according to the present disclosure is not limited to the above-mentioned embodiments as long as the built-in member with a higher melting temperature than the sealing layer is disposed at the outer periphery of the capacitor part in the in-plane direction. Accordingly, with regard to the configuration, manufacturing conditions, or other features of the capacitor array, various modifications or variations can be made within the scope of the present disclosure.

The capacitor element of the capacitor array according to the present disclosure is not limited to an electrolytic capacitor such as a solid electrolytic capacitor. The capacitor element of the capacitor array according to the present disclosure may constitute, for example, a ceramic capacitor using barium titanate, a thin film capacitor using silicon nitride (SiN), silicon dioxide (SiO₂), hydrogen fluoride (HF), or other materials, or a trench capacitor having a metal-insulator-metal (MIM) structure.

From the viewpoint of decreasing the thickness and increasing the area of the capacitor part, as well as improving the mechanical characteristics of the capacitor part such as rigidity and flexibility, preferably, the capacitor element constitutes a capacitor made of a metal such as aluminum as its base material, or more preferably, the capacitor element constitutes an electrolytic capacitor made of a metal such as aluminum as its base material.

The capacitor array according to the present disclosure is used in, for example, a composite electronic component. Such a composite electronic component includes, for example, the capacitor array according to the present disclosure, and an electronic component electrically connected to the outer electrode layer of the capacitor array according to the present disclosure.

In the composite electronic component, the electronic component electrically connected to the outer electrode layer may be a passive element, may be an active element, may be each of a passive element and an active element, or may be a composite of a passive element and an active element.

A non-limiting example of the passive element is an inductor.

Non-limiting examples of the active element include a memory, a graphical processing unit (GPU), a central processing unit (CPU), a micro processing unit (MPU), and a power management IC (PMIC).

If the capacitor array according to the present disclosure is used in a composite electronic component, the capacitor array according to the present disclosure is handled as, for example, a substrate to which an electronic component is to be mounted. Accordingly, if the capacitor array according to the present disclosure as a whole is formed in sheet form and, further, the electronic component to be mounted to the capacitor array according to the present disclosure is formed in sheet form, the capacitor array according to the present disclosure, and the electronic component can be electrically connected in the thickness direction via a through-hole conductor that extends through the electronic component in the thickness direction. As a result, an active element and a passive element each serving as such an electronic component can be constructed as if these elements constitute a unified module.

For example, a switching regulator can be formed by electrically connecting the capacitor array according to the present disclosure between a voltage regulator including a semiconductor active element, and a load that receives supply of a converted direct-current voltage.

In the composite electronic component, a circuit layer may be formed on one major face of a capacitor matrix sheet, which is a sheet where a plurality of the capacitor arrays according to the present disclosure are laid out, and the circuit layer may then be electrically connected to a passive element or an active element that serves as an electronic component.

The capacitor array according to the present disclosure may be disposed in a cavity that is formed in a substrate in advance, and after the cavity is filled with resin, a circuit layer may be formed on the resin. A passive component or an active component that serves as another electronic component may be mounted in another cavity provided in the same substrate.

In an alternative possible configuration, the capacitor array according to the present disclosure is mounted to a smooth carrier such as a wafer or glass, and after an outer layer part made of resin is formed, a circuit layer is formed, and then the circuit layer is electrically connected to a passive element or an active element that serves as an electronic component.

The following features are disclosed herein.
<1>A capacitor array including: a capacitor part including a plurality of capacitor elements disposed in a planar arrangement in an in-plane direction orthogonal to a thickness direction, the plurality of capacitor elements including mutually adjacent capacitor elements that are separated from each other, wherein the plurality of capacitor elements each include a first electrode layer and a second electrode layer that face each other in the thickness direction with a dielectric layer interposed between the first electrode layer and the second electrode layer; a built-in member disposed at an outer periphery of the capacitor part in the in-plane direction; and a sealing layer that seals the capacitor part and the built-in member, wherein the built-in member has a higher melting temperature than the sealing layer.
<2>The capacitor array according to <1>, in which the built-in member includes a configuration identical to a configuration of each of the plurality of capacitor elements, and is spaced apart and electrically insulated from the capacitor part.
<3>The capacitor array according to <1>or <2>, in which a width between the built-in member and the capacitor part decreases along the thickness direction.
<4>The capacitor array according to any one of <1>to <3>, in which the built-in member is exposed from the sealing layer in the in-plane direction.
<5>The capacitor array according to any one of <1>to <4>, in which the first electrode layer is an anode plate, the anode plate having a core made of metal, and a porous part on at least one major face of the core, in which the dielectric layer is on a surface of the porous part, and in which the second electrode layer is a cathode layer on a surface of the dielectric layer.
<6>The capacitor array according to <5>, in which the cathode layer includes a solid electrolyte layer on the surface of the dielectric layer.
<7>The capacitor array according to <5>or <6>, in which the built-in member has a height at least equivalent to a thickness of the anode plate.
<8>The capacitor array according to any one of <5>to <7>, in which the built-in member includes a configuration identical to a configuration of the anode plate, and is spaced apart and electrically insulated from the capacitor part.
<9>The capacitor array according to any one of <5>to <8>, in which a width between the built-in member and the capacitor part decreases along the thickness direction.
<10>The capacitor array according to any one of <5>to <9>, in which the built-in member is exposed from the sealing layer in the in-plane direction.

### REFERENCE SIGNS LIST

1, 1a, 1A, 2, 2A capacitor array
10 capacitor element
11 anode plate (first electrode layer)
11A core
11B porous part
12 cathode layer (second electrode layer)
12A solid electrolyte layer
12B electric conductor layer
13 dielectric layer

20 capacitor part
30 sealing layer
35 insulating layer
40, 40A, 40B, 40C, 40D, 40E, 41 built-in member
50 outer electrode layer
51 first outer electrode layer
52 second outer electrode layer
60 embedded resin layer
70 through-hole conductor
71 first through-hole conductor
72 second through-hole conductor
81 first through-hole
82 second through-hole
90 via-conductor
100 capacitor array sheet
110 through-groove
120 slit
130 insulating resin sheet
CL cutting line

1. A capacitor array comprising:
a capacitor part including a plurality of capacitor elements disposed in a planar arrangement in an in-plane direction orthogonal to a thickness direction, the plurality of capacitor elements including mutually adjacent capacitor elements that are separated from each other, wherein the plurality of capacitor elements each include a first electrode layer and a second electrode layer that face each other in the thickness direction with a dielectric layer interposed between the first electrode layer and the second electrode layer;
a built-in member disposed at an outer periphery of the capacitor part in the in-plane direction; and
a sealing layer that seals the capacitor part and the built-in member, wherein the built-in member has a higher melting temperature than the sealing layer.

2. The capacitor array according to claim 1, wherein the built-in member includes a configuration different from a configuration of each of the plurality of capacitor elements.

3. The capacitor array according to claim 1, wherein the built-in member is electrically insulated from the capacitor part.

4. The capacitor array according to claim 1, wherein the built-in member is spaced apart from the capacitor part.

5. The capacitor array according to claim 1, wherein the built-in member includes a configuration identical to a configuration of each of the plurality of capacitor elements, and is spaced apart and electrically insulated from the capacitor part.

6. The capacitor array according to claim 4, wherein a width between the built-in member and the capacitor part decreases along the thickness direction.

7. The capacitor array according to claim 1, wherein the built-in member is exposed from the sealing layer in the in-plane direction.

8. The capacitor array according to claim 1, wherein the built-in member is unexposed from the sealing layer in the thickness direction.

9. The capacitor array according to claim 1, wherein the built-in member is made of an insulating material.

10. The capacitor array according to claim 1,
wherein the first electrode layer is an anode plate, the anode plate having:
a core made of metal, and
a porous part on at least one major face of the core,
wherein the dielectric layer is on a surface of the porous part, and
wherein the second electrode layer is a cathode layer on a surface of the dielectric layer.

11. The capacitor array according to claim 10, wherein the cathode layer includes a solid electrolyte layer on the surface of the dielectric layer.

12. The capacitor array according to claim 10, wherein the built-in member has a height at least equivalent to a thickness of the anode plate.

13. The capacitor array according to claim 10, wherein the built-in member includes a configuration different from a configuration of each of the plurality of capacitor elements.

14. The capacitor array according to claim 10, wherein the built-in member is electrically insulated from the capacitor part.

15. The capacitor array according to claim 10, wherein the built-in member is spaced apart from the capacitor part.

16. The capacitor array according to claim 10, wherein the built-in member includes a configuration identical to a configuration of the anode plate, and is spaced apart and electrically insulated from the capacitor part.

17. The capacitor array according to claim 10, wherein a width between the built-in member and the capacitor part decreases along the thickness direction.

18. The capacitor array according to claim 10, wherein the built-in member is exposed from the sealing layer in the in-plane direction.

19. The capacitor array according to claim 10, wherein the built-in member is unexposed from the sealing layer in the thickness direction.
